(19) United States
(12) Patent Application Publication
(10) Pub. No.: US 2018/0145534 A1
(43) Pub. Date: May 24, 2018

(54) Photovoltaic device with off and on electric field

(71) Applicant: Sijiu Liu, Cupertino, CA (US)

(72) Inventor: Sijiu Liu, Cupertino, CA (US)

(21) Appl. No.: 15/356,600

(22) Filed: Nov. 20, 2016

(51) Int. Cl. H02J 7/35; H01L 31/05; H02J 7/00; H02S 40/38

(52) U.S. Cl. CPC H02J 7/355; H01L 31/0504; H02J 7/345; H02S 40/38; H02J 7/0068

(57) ABSTRACT

Each cell of the photovoltaic device comprises two promotion layers, across which an off and on electric field, other than a standing one, is coupled with a desired high DC voltage. The high DC voltage is distributed through a promotion-circuit to the entire promotion layers in the panels. When it is at the “on” interval, the high DC voltage field exerts a strong attraction force to attract and hold extra electric charges for the collection layers to collect. When it is at the “off” interval the strong attraction force of the electric field is disarmed so that the extra electric charges held by the electric field are free and can be conducted into the super capacitor-battery. With the alternation of the “off” and “on” intervals the device substantially increases its efficiency.

### BACKGROUND OF THE INVENTION

### The Technical Field of the Invention

This invention relates to the commercial photovoltaic device or solar cell, more particularly to an electric field besides the built-in electric field in the p-n junction. The purpose of the invention is to substantially raise the efficiency for the photovoltaic industry.

### The Cause of the Low Photovoltaic Efficiency

It is well-known that the atoms of semiconductor materials under the sun can absorb the energy of photons and cause some electrons jumping out of their normal orbits and becoming free electrons. Meanwhile the same numbers of protons' positive charges are left behind which is referred to as “holes”. The free electrons together with the holes are called electron-hole pairs. Only in a very short time can some of the electrons and holes be conducted to flow to opposite directions and be collected as electricity ready for human use. In other words, most of the electrons and holes unfortunately re-combine with each other before being collected. In this case, this part of light energy is wasted in the form of heat.

Because the electron-hole pairs' re-combination rate is high, the photoelectric conversion efficiency is low; the current photovoltaic industry has an overall efficiency rate only around 10-15%, some of them even below 10%. Under such low efficiency level the photovoltaic industry can hardly gain profit and be sustainable without government subsidization.

Can the re-combination rate be greatly brought down so that to substantially increase the photovoltaic efficiency? There are different theories for the question: Pessimists attribute the unsatisfied current situation to a theoretical limit of the photoelectric conversion calculated by some scientists; but optimists believe that any theoretical limit has to be limited by its era, during which the level of the related science and technology should not be considered as the final truth; therefore, with the advance of technique and design method the theoretical limit has to be updated.

### The Prior Arts in this Field

In the recent decades some inventors believe that the high recombination rate of electron-hole pairs, hence the low photoelectric conversion efficiency may be caused by the low strength of the built-in electric field in p-n junction. So, the following inventions have tried to add an additional electric field to promote the collection of electricity. For example, the following patent numbers or the published application numbers: DE 4227504 (1994), CN 101826566 (2010), CN 102064213 (2011), CN 103199131 (2013), AU 2015200219 (2015), U.S. Pat. No. 8,536,444 (2015), US 2015/0340989 (2015), and US 2016/0118514 (2016) all provided an extra electric field in their inventions. Most of the above prior arts are powered by either self-generated or external electricity. The last one (US 2016/0118514) is even so smart that does not have to spend any electricity to sustain the electric field; it uses a resin-based film implanted with electrons or ions by the method of corona discharging technique; therefore, the film acts as a standing electric field, which does not need electricity any more to power it after manufacturing.

However, no matter how smart or sophisticates those designs are, the extra electric field of all the above inventions cannot help to produce more electricity than without the extra field so far. The reason is in the nature of electric field. Any electric field, of course, has the ability to attract and acquire electrons and holes onto its two poles respectively; however, the added electric field also has the ability to hold and prevent the electrons and holes from conducting away from the field once they are acquired. As a result, the added electric field cannot help to produce more electricity than without it. One may argue that each pole of the field can at least repel the like charges away, so that to prevent the two kinds of charges from re-combining with each other. Yes, temporarily it is; but when the two kinds of charges reach their own poles (dislike in polarity), they will also be held there and against being collected for human use. This phenomenon is very similar to that of a permanent magnet: indeed it has the ability to attract and acquire iron debris; but it also has the ability to hold them against being taken away freely unless an extra energy is applied to force them away. It is the nature of the magnet.

The present invention provides a novel solution without going against any natural law; that is to adopt an off and on electric field, instead of a standing one that all the prior arts adopted. Best of all, this novel solution does not require manufacturers to change their existing equipment they have, so that they don't have to invest more money or to postpone or cancel their commercial contracts. This novel solution only involves in the design of electric circuits and layer deposition sequence.

### BRIEF SUMMARY OF THE INVENTION

With a novel promotion system the goal of the present invention is to substantially increase, at least double, the current average photovoltaic efficiency in this industry. The present photovoltaic device comprises at least the following five major components: (1) A pair of two capacitor-like structure in each solar cell of the device, wherein each of the capacitor-like structure consisting of three layers—an insulation film being sandwiched by two TCO- or graphene-made thin layers; (2) a semiconductor member which is sandwiched by the above pair of the capacitor-like structure, wherein the two TCO- or graphene-made thin layers that next to the semiconductor member acting as the collection layers to collect the electric charges through a collection-circuit, the bus bar, and the other two layers that not next to, as the promotion layers; across which (3) an off and on electric field being coupled and powered by any source of DC electricity, that works in an off and on mode; through (4) a promotion-circuit connecting in parallel to each of the promotion layers in the panels of the device for distributing the off and on electric field; and (5) a commercial timing relay is inserted in the collection-circuit for automatically switching the “off” and “on” intervals of the electric field and for executing the length of the two intervals.

At the “on” interval, the positive promotion layer with the positive pole of the electric field attracts extra negative charges (electrons) for the negative collection layer to collect; at the same time, the negative promotion layer with the negative pole of the field attracts extra positive charges (holes) for the positive collection layer to collect. Thus, those extra electric charges of the electron-hole pairs are diverged to flow towards different poles (layers) and are held there, respectively. As a result, the re-combination rate of the electron-hole pairs from the semiconductor member is lowered and the photovoltaic efficiency is raised.

Among the two intervals, the “off” interval plays a special roll that is a brief break of the electric field to disarm the electric field and hence to free the electric charges that were attracted and held in the “on” interval of the field. In other words, only in the “off” intervals can the electric charges be free and collected into a super capacitor-battery for human use. The commercial timing relay should be preset with the length of the two intervals, for the “off” intervals (lasting only a few seconds) and the “on” intervals (may lasting up to a minute or more) respectively.

### BRIEF DESCRIPTION OF THE FIGURES

FIG. 1 is a cross-section view of a single solar cell of the present invention, in which the semiconductor member is sandwiched by two “capacitor-like” structures.

FIG. 2 is a diagram that vividly depicts the way of layer connections in the two “capacitor-like” structures: the layers with same polarity in different “capacitor-like” structures are connected with each other.

FIG. 3 is the same design as FIG. 2 but expressed in the form of ordinary electric circuit. This design is characterized as low voltage promotion type.

FIG. 4 is a high voltage promotion type with a novel promotion system, in which the five major component parts are shown. This figure is characterized by the off and on electric field powered by its self-generated electricity.

FIG. 5 shows another high voltage promotion type similar to the FIG. 4, but the off and on electric field is powered by external electricity. And there is only one layer of the semiconductor member that has no built-in electric field.

### DETAILED DESCRIPTION OF THE EMBODIMENTS

While the invention will be described in conjunction with these specific embodiments, it will be understood that it is not intended to limit the invention to such specific embodiments. On the contrary, it is intended to cover alternatives, modifications, and equivalents as may be included within the spirit and scope of the invention. For instance, in the present invention some embodiments provide two layers of semiconductor layers 6; other embodiments provide only one layer of semiconductor layer 6; under the same spirit they may exchange their layers with each other; even provide more than two layers of the semiconductor member 6. In other instances, some well-known mechanical or electronic apparatuses have not been described in details in order to avoid unnecessarily obscure the present invention.

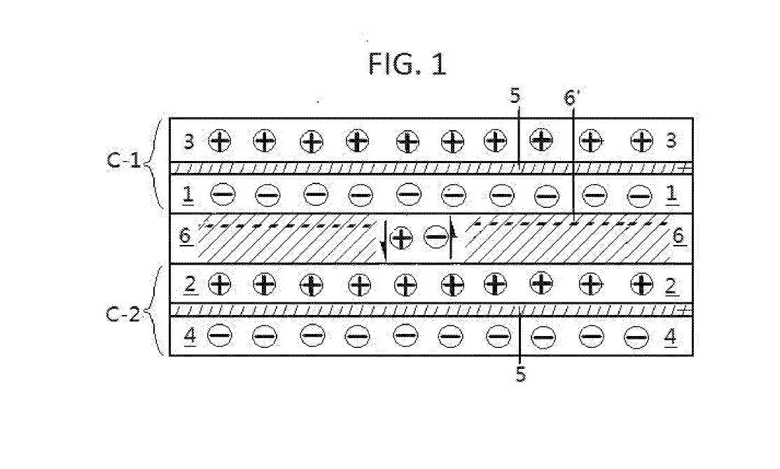

For convenience, it is better to describe the basic layer design which is common to all the embodiments. Referring to FIG. 1, it comprises a semiconductor member 6 with two layers that forming one p-n junction 6′ with one built-in electric field. The semiconductor member 6 can be made of a variety of materials such as silicon-based or organic material, or the material of chemical compounds with a variety of different junctions such as p-i-n junction.

In order to collect the two kinds of electric charges (electrons and holes) the semiconductor member 6 is sandwiched by a pair of charge collection layers 1 and 2 (equivalent to the two contacts or electrodes in traditional solar cells); both are made of transparent conductive oxide (TCO) or graphene films. The negative collection layer 1 is directly deposited on front surface of the semiconductor member 6; the positive collection layer 2 is beneath the member 6. The character of the present invention is that the resulted sandwich structure (three layers of them) is sandwiched again by another pair of TCO made promotion layers 3 and 4, across which the off and on electric field is coupled. A positive promotion layer 3 is deposited above the negative collection layer 1, and a negative promotion layer 4 is under the positive collection layer 2. The promotion layers (3 and 4) are electrically isolated with the collection layers (1 and 2) by a transparent insulation film 5 in between respectively. The transparent insulation film 5 can be made of a variety of dielectric film, or plastic and synthetic fiber materials, the polyester for example. As a result of the above layer arrangement, the present invention has actually created two “capacitor-like” structures C-1 (1+5+3) and C-2, (2+5+4) (see FIG. 1). The property of capacitor is its fast charging and discharging if there is a proper design of electric circuit.

### Embodiment #1—Low Voltage Promotion

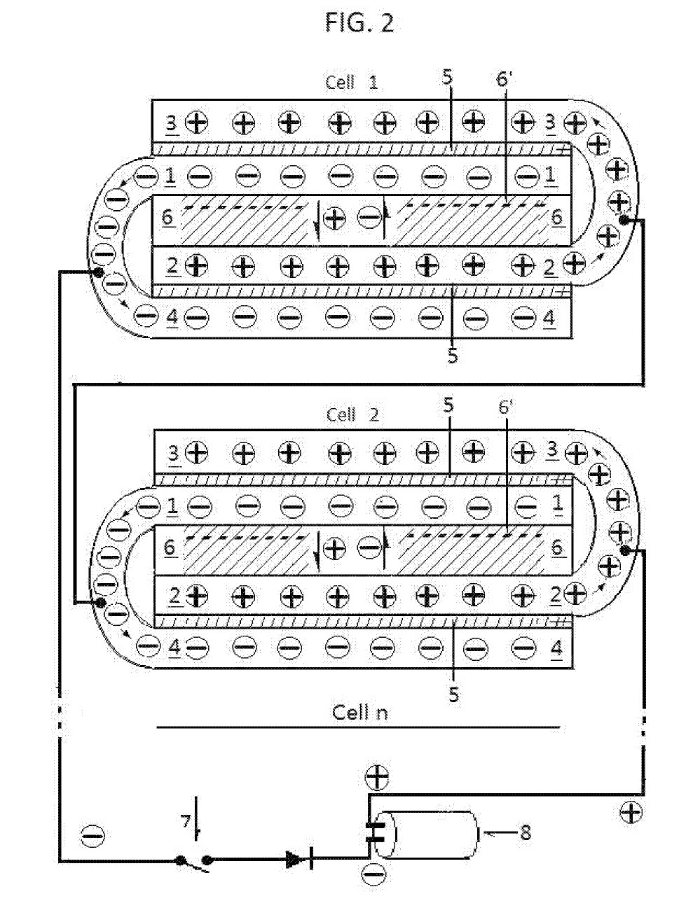

With reference to FIG. 2 when the commercial timing relay 7, inserted in the collection-circuit, is at the open position (disconnected from the battery) the electric field starts its “on” interval, since the solar cell collects electric charges independently under the light. When the timing relay 7 shifts to the closed position (connected to the battery) the electric field starts its “off” interval, since most of the electric charges from all the four layers 1, 2, 3, and 4 discharge into battery that causes the electric field short of electric charges.

Now, the promotion mechanism in this embodiment is like this: the negative collection layer 1 (i.e. negative electrode or contact) is connected to the negative promotion layer 4 in the same cell to share the negative charges collected; whereas the positive collection layer 2 (i.e. positive electrode or contact) is connected to the positive promotion layer 3 in the same cell to share the positive charges collected. Thus, on one hand, both negative and positive charges can be temporarily stored in the promotion layers 4 and 3 respectively (note the flowing arrows); on the other hand, the stored charges (the self-generated electricity), form the electric field and attract extra electric charges for the collection layers 1 and 2 to collect, respectively. Because the sharing and promoting occur inside each solar cell, the above promotion is in a low voltage level. Of course, all the cells on a panel can be connected in series to raise the total voltage as the traditional solar panel.

### Embodiment #2—Low Voltage Promotion (2)

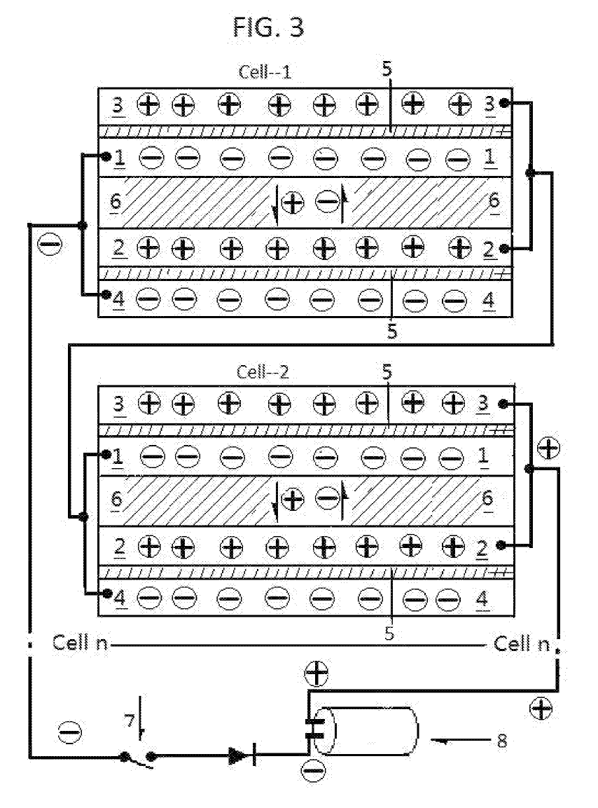

With reference to FIG. 3 (a cross sectional view in the form of circuit) this embodiment is essentially the same with the embodiment #1; the only difference is that there is no p-n junction or built-in electric field in the semiconductor member 6 of #2. The semi-conductor member 6 in #2 is doped with only one dopant, n or p type. At first it seems impossible to build this kind of solar cell but it is still possible in the present invention. The two promotion layers 3 and 4 with the shared positive and negative electric charges respectively have actually created a “built-out” electric field, which has the same function to diverge the electric charges flowing to different layers and finally to the battery as the traditional built-in electric field does. The amplitude of the “built-out” electric field is theoretically no limitation comparing to the built-in electric field, which is limited below 1 volt. So, when the voltage of the built-out electric field is high enough the built-in electric field can be omitted as it may act as impedance to the minority charges while they cross the field. In this case the embodiment needs only one layer of the semiconductor member 6. If we consider the above two embodiments as mostly the explanatory ones the following embodiments are the favorite ones of the present invention.

### Embodiment #3—High Voltage Promotion

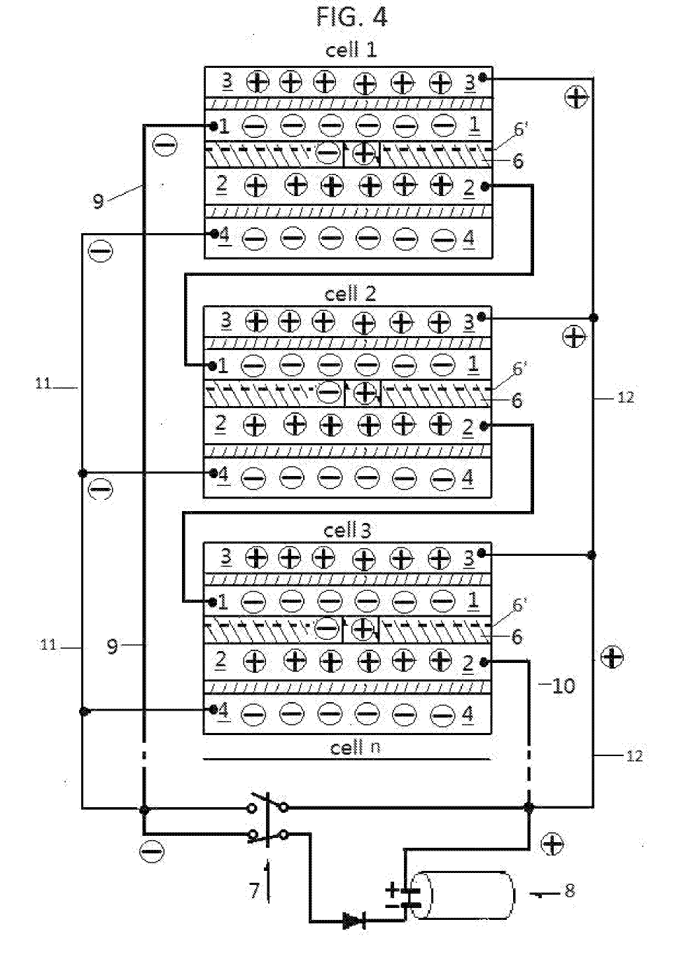

With reference to FIG. 4, a cross sectional view of the present invention, this preferred embodiment shows how the self-generated high electric voltage is used in the promotion system. To manufacture and install this type of solar cell with the five major components mentioned earlier the following three steps are essential:

Step 1, connecting in series enough number of negative and positive collection layers, 1 and 2, head to tail, in the panels of the device through the collection-circuit (9+10) to obtain a desired high DC voltage. Step 2, connecting in parallel the negative and positive promotion layers 4 and 3, respectively, in the panels through the promotion-circuit (11+12) to distribute the desired high DC voltage. Step 3, inserting a commercial timing relay 7 in between the collection-circuit (9+10) and the battery 8. The relay 7 performs two actions, the connection and disconnection; the connection causes the “off” interval of the electric field, and the disconnection causes the “on” interval of the field. The relay 7 shifts the two actions in turn automatically (see FIG. 4) by presetting the connection action at a voltage that approaching to the desired high; and the disconnection action at the voltage down approaching to its half. When the electric field is at “on” interval the promotion layers 4 and 3 in the panels shire the desired high DC voltage and exert their strong attraction force to attract extra electric charges (from the semiconductor layer) for the collection layers to collect.

When the electric field is at the “off” interval the most important thing occurs: all the negative and positive electric charges attracted, acquired and accumulated in the layers 1, 2, 3, and 4 become free and therefore, can be collected by a super capacitor-battery 8. In other words, only at the “off” interval can the electric charges be conducted to and stored in the battery 8 for human use.

Thus, by adding the off and on electric field, the two kinds of electric charges of the electron-hole pairs are diverged to flow towards different layers, respectively. As a result, the re-combination rate of electron-hole pairs in the semiconductor member 6 is mostly prevented.

The photovoltaic device of the present invention works in most time at “on” intervals to collect and accumulate electric charges; while only in a very short time at “off” intervals. The length of “off” interval ranges 1-5 seconds to discharge the electric charges, depending on the internal resistance of the cells; but the length of “on” interval can be tens times longer than “off” interval, depending on the desired high voltage preset and the local sunlight intensity. The present invention also inserts a diode in the collection-circuit (9+10) to prevent electricity flowing back into the device, especially at night when the solar device does not work. In addition, a commercial “battery charger” or something similar (not shown in the figures) may be inserted in circuit to optimize the parameters of the current, voltage, etc., as the industry usually does.

In general, it is the above unique promotion system that enables all the promotion layers 3 and 4 sharing the desired high voltage and helps the collection layers 1 and 2 attracting extra electric charges Moreover, it is the above unique and practical means that will provide the solar industry the most desirable photovoltaic efficiency that is hopefully to double the current average efficiency of the commercial products, except the concentration type.

### Embodiment #4—Another High Voltage Promotion Type

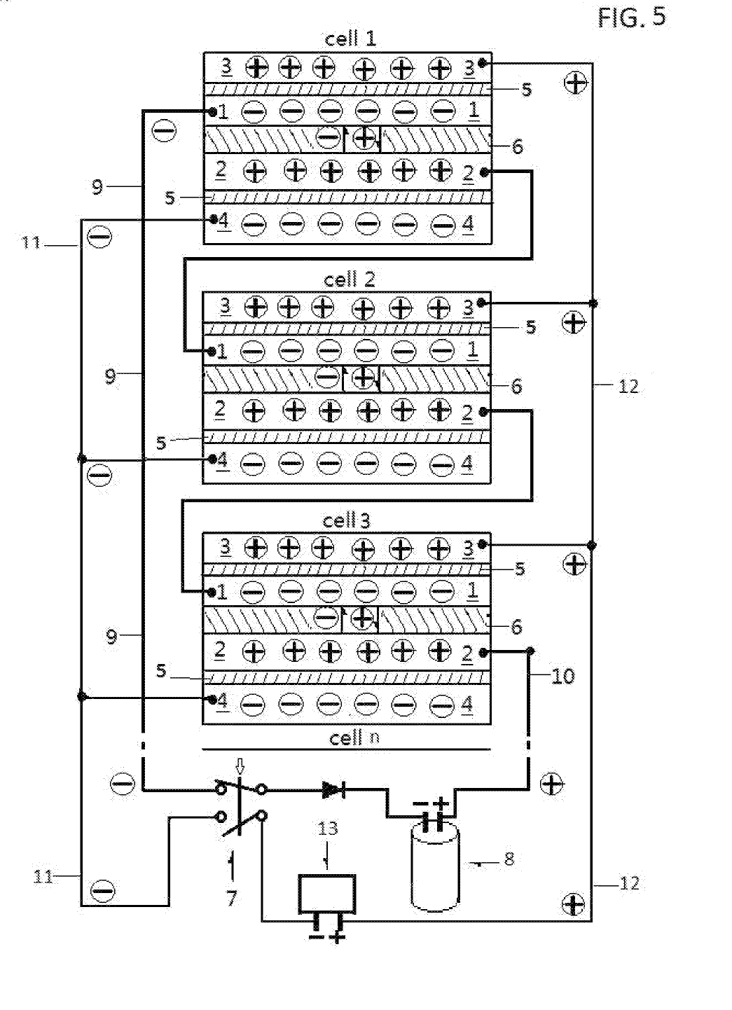

This embodiment is another preferred one, which is almost the same as the embodiment #3 except two differences: one is that the off and on electric field of this embodiment is powered by the external electricity (utility and its stored form, battery) with a transformer 13 to get the desired high DC voltage (the #3 is powered by self-generated electricity). Another difference is that there is no any junction or built-in electric field, since this embodiment comprises only a single layer of semiconductor member 6. The material of the semiconductor 6 chosen in the embodiments #3 and #4 are the same i.e. the silicon-based semiconductors, or semiconductors of organic, or chemical compound. Referring to FIG. 5, the thickness of the semiconductor layer 6 can be the traditional thick layer, or the amorphous thin films. Since the thickness of the built-in electric field (the depletion zone) is only a fraction of the whole layer, and whose function is mostly limited inside the depletion zone; therefore, if the voltage of the built-out electric field is high enough, the function of the built-in electric field is negligible. It is the basic reason for the embodiments that the p-n junctions can be omitted. In order to extract and acquire as many electrons and holes as possible, the electric field should have a high voltage, much higher than the built-in electric field. The voltage needed is affected by the distance from the semiconductor 6 to the promotion layers 4 or 3. This distance is actually determined by the thickness of the collection layer (1 or 2) plus the thickness of the transparent insulation film 5. The thicker these two layers are the higher the voltage is needed. Therefore, the TCO layers should be made as thin as possible; alternately, the graphene layer is even better. The transparent insulation film 5 should also be as thin as possible. From the view point of safety, the range of the high voltage in the United States is around 110V, which is considered causing less injury to human body. However, the voltage of 220V or more for most home appliances with proper safety measurement is considered acceptable in many countries in the world. So, the highest voltage for the present invention should not be limited by 220V.

Referring to FIG. 5, the ⊖ and ⊕ signs, representing the negative and positive electric charges respectively, appear everywhere in the FIG. 1-5 but one doesn't have to worry about the short circuit. Because the negative and positive charges can meet or contact nowhere in the device; they can only face to face besides the thin insulation film 5 in the “capacitor-like” structures. Therefore, the off and on electric field added in the present photovoltaic device does not spend or consume much external or self-generated electricity because there is no closed circuit for the electric charges in the device to flow and the insulation film 5 blocks most of them. When the timing relay 7 continuously alternates the connection and disconnection it may consume a tiny amount of energy but that is almost negligible. The collection-circuit (9+10), and the promotion-circuit (11+12) are indicated by thick and thin lines respectively.

### Description of the Materials Used in the Present Invention

The above mentioned charge collection layers 1 and 2 and the promotion layers 3 and 4, are all made of transparent conductive oxide (TCO) films, which have a long list of prior art for users to choose, including, but not limited to, ITO (In₂O₃), ZnO, SnO₂, Cd₂SnO₄, etc. With different deposition equipment a company has or different demands of commercial orders, manufacture companies can choose the suitable TCO and appropriate thickness of the films; here is no need to provide a complete list of the TCO films, but a particular material, the graphene, needs to be recommended here, if the cost is not too high. As to the transparent insulation layers, one can also choose suitable oxide film like SiO₂, Al₂O₃, or suitable plastic films, if only the transparency and insulation properties are good.

The present invention is designed for both the thin film solar cells and the conventional solar cells; either deposit on a rigid back substrates or on a flexible plastic film; either for family based small scale solar panels, or for big buildings and large scale industrial power plants. Likewise, to select semiconductor materials for the present invention, there is also a long list of candidates of prior art to choose, including, but not limited to, the silicon-based semiconductor including the amorphous silicon, the organic semiconductors, and the semiconductors of chemical compounds, for example, CIGS, CIS, CdTe, CdS, ZnS, ZnO, etc; they can be used alone or in any combination in the present invention.

In the present invention the layer structure includes only seven layers, however, one or more layers of prior arts can also be integrated optionally, such as the front layer or film that reduce sun light reflection, or passivation, the bottom mirror for re-capture some sun light reflected, etc.

What is claimed is:

1. A photovoltaic device comprising the following five major component parts:
a pair of capacitor-like structures in every solar cells, wherein each of the capacitor-like structure having two TCO- or graphene-made thin layers with a transparent insulation film in between;
a semiconductor member which is sandwiched by the pair of capacitor-like structures, wherein the two thin layers that next to the semiconductor member acting as collection layers to collect the electrons and holes, respectively, and the other two layers acting as promotion layers; across which
an off and on electric field being coupled with and powered by any source of DC electricity that works in an off and on mode; through
a promotion-circuit connecting in parallel to each of the promotion layers in the panels of the device for distributing the off and on electric field; and
a relay being inserted between the battery and the collection-circuit for automatically switching between the “off” and “on” intervals of the electric field and for executing the length of each interval.

2. The photovoltaic device according to claim 1, wherein the any source of DC electricity is self-generated high voltage DC electricity by serial connecting as many collection-layers as desired in the panels of the photovoltaic device.

3. The photovoltaic device according to claim 1, wherein the any source of DC electricity is external, including the utility electricity and its stored form, battery; both being transformed into the desired high DC voltage.

4. The photovoltaic device according to claim 1, wherein the high voltage of the any source of DC electricity chosen for promotion is from 22V up to, but is not limited to, 220V in some embodiments and the low voltage chosen is from 1 to 21V in other embodiments.

5. The photovoltaic device according to claim 1, wherein a super capacitor is utilized as battery for taking its advantages of fast charging and discharging properties.

6. The photovoltaic device according to claim 1, wherein the semiconductor member is the one that chosen from the following four layer-configurations: a, one layer, n or p type; b, two layers, with a p-n or n-p junction; c, three layers with p-i-n junction; d, four or more layers with n-p or n-p junctions alternatively piled up one on another.

7. The photovoltaic device according to claim 1, wherein the length of the “off” interval, ranging 1-5 seconds, and the length of “on” interval, ranging from up to one minute to 5 minutes, are determined by voltage preset and the local weather condition.
